(19) United States
(12) Patent Application Publication
(10) Pub. No.: US 2006/0093159 A1
(43) Pub. Date: May 4, 2006

(54) Method and apparatus to compensate for frequency characteristic of earphones

(76) Inventors: You-kyung Koh, Seoul (KR); Joon-hyun Lee, Seongnam-si (KR); Jong-bae Kim, Seoul (KR)

Correspondence Address: STANZIONE & KIM, LLP, 919 18TH STREET, N.W., SUITE 440, WASHINGTON, DC, 20006, US

(21) Appl. No.: 11/126,243

(22) Filed: May 11, 2005

(30) Foreign Application Priority Data
Nov. 2, 2004 (KR) 2004-88174

(51) Int. Cl. H03G 5/00; H04R 1/10

(52) U.S. Cl. 381/98; 381/74

(57) ABSTRACT

An earphone frequency characteristic compensating method and apparatus to compensate for a frequency response characteristic of earphones by selecting a target curve. The method includes measuring the frequency response characteristic of the earphones considering a frequency characteristic of an ear canal, extracting a filter coefficient by comparing the measured frequency response characteristic of the earphones with a frequency characteristic of a target curve, and compensating for the frequency response characteristic of the earphones based on the extracted filter coefficient.

### CROSS-REFERENCE TO RELATED APPLICATIONS

This application claims the priority under 35 U.S.C. § 119 of Korean Patent Application No. 2004-88174, filed on Nov. 2, 2004, in the Korean Intellectual Property Office, the disclosure of which is incorporated herein in its entirety by reference.

### BACKGROUND OF THE INVENTION

1. Field of the Invention

The present general inventive concept relates to an earphone sound quality compensation system, and more particularly, to an earphone frequency characteristic compensating method and apparatus to compensate for a frequency response characteristic of earphones by selecting a target curve.

2. Description of the Related Art

Earphones are a transducer for converting electrical signals to sound waves, and fit close to a wearer's ears to transfer the sound directly into the wearer's ears. Earphones are used to reproduce sound from portable audio devices, such as MP3 players. Conventional earphones are used without compensation for uneven frequency response characteristics. Also, in order to compensate for poor frequency characteristics due to the small speakers in earphones, manufacturers install equalizer filters to provide a rock mode or a jazz mode in portable audio devices. However, when the listener uses earphones provided by another manufacturer instead of the original ones, the built-in equalizer data does not match the different earphones. Furthermore, equalizer data on all earphones from a plurality of manufacturers cannot be stored in the portable audio device.

Also, if a plurality of preset equalizer modes are stored in the portable audio device in order to compensate for the poor performance of the earphones, the user can select the wrong mode, and actually reduce the performance further.

### SUMMARY OF THE INVENTION

The present general inventive concept provides an earphone frequency characteristic compensating method to compensate for a frequency response characteristic of earphones by selecting a target curve.

The present general inventive concept also provides an earphone frequency characteristic compensating apparatus to compensate for a frequency response characteristic of earphones by selecting a target curve.

Additional aspects of the present general inventive concept will be set forth in part in the description which follows and, in part, will be obvious from the description, or may be learned by practice of the general inventive concept.

The foregoing and/or other aspects of the present general inventive concept are achieved by providing an earphone frequency characteristic compensating method including measuring a frequency response characteristic of earphones considering a frequency characteristic of an ear canal, extracting a filter coefficient by comparing the measured frequency response characteristic of the earphones with a frequency characteristic of a target curve, and compensating for the frequency response characteristic of the earphones based on the extracted filter coefficient.

The forgoing and/or other aspects of the present general inventive concept are also achieved by providing an earphone frequency characteristic compensating apparatus including an ear-shaped simulator which includes earphones and a microphone, a signal analyzer to output a stimulus to the ear-shaped simulator and to analyze a frequency of a signal generated by the ear-shaped simulator in response to the stimulus, an earphone signal compensator to measure a frequency response characteristic of the earphones based on the frequency analyzed by the signal analyzer, to extract a filter coefficient by comparing the measured frequency response characteristic of the earphones with a frequency characteristic of a target curve, and to compensate for the frequency response characteristic of the earphones based on the extracted filter coefficient.

### BRIEF DESCRIPTION OF THE DRAWINGS

These and/or other aspects of the present general inventive concept will become apparent and more readily appreciated from the following description of the embodiments, taken in conjunction with the accompanying drawings of which:

FIG. 1 is a block diagram of a system to compensate for a frequency characteristic of earphones according to an embodiment of the present general inventive concept;

FIG. 2 is a cross-sectional view of an earphone measuring portion of a head and torso simulator of the system of FIG. 1;

FIG. 3 is a flowchart illustrating a method of compensating for a frequency characteristic of earphones according to an embodiment of the present general inventive concept;

FIG. 4 is an example illustrating a response characteristic of reference earphones measured using the head and torso simulator of the system of FIG. 1;

FIG. 5 is an example illustrating an ear characteristic curve measured in a diffuse field; and

FIG. 6 is a flowchart illustrating a design of a digital filter coefficient to be applied to a portable audio apparatus according to an embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

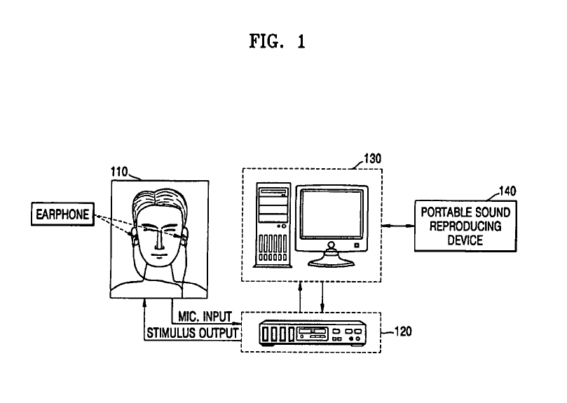

FIG. 1 is a block diagram illustrating a system to compensate for a frequency characteristic of earphones according to an embodiment of the present general inventive concept.

Referring to FIG. 1, the earphone frequency characteristic compensating system includes a head and torso simulator 110, a signal analyzer 120, a personal computer (PC) 130, and a portable audio device 140.

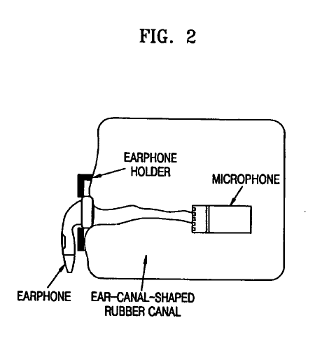

The head and torso simulator 110 can be a mannequin including human ears in which earphones are inserted in order to compensate sound output from the portable audio device 140. The head and torso simulator 110 includes the earphones, a microphone (see FIG. 2), and a microphone amplifier (not shown).

The signal analyzer 120 outputs a stimulus, which is a random signal, to the head and torso simulator 110, and analyzes a frequency of a signal generated by the head and torso simulator 110 in response to the stimulus.

The PC 130, which is a device to compensate for a frequency response characteristic of the earphones, stores a program to input frequency characteristic data analyzed by the signal analyzer 120, to analyze the characteristics of the earphones according to the input characteristic data, and to calculate an equalizer for the earphones according to the analyzed characteristics of the earphones. That is, the PC 130 measures the frequency response characteristic of the earphones based on the frequency analyzed by the signal analyzer 120, extracts a filter coefficient by comparing the measured frequency response characteristic of the earphones with a frequency characteristic of a target curve, and compensates for the frequency response characteristic of the earphones based on the extracted filter coefficient.

The portable audio device 140 downloads the filter coefficient extracted by the PC 130, and compensates the sound output to the earphones according to the downloaded filter coefficient.

FIG. 2 is a cross-sectional view illustrating an earphone measuring portion of the head and torso simulator 110 of FIG. 1.

The human ear has the ear canal between the auricle and the eardrum, and a specific frequency band is amplified due to resonance of the ear canal. Referring to FIG. 2, an earphone holder is installed to hold an earphone close to an ear-canal-shaped rubber molding resembling the shape and quality of the human ear, and a microphone is installed at the location of the eardrum. Therefore, the earphone frequency response characteristic of the portable audio device 140 is measured using an impulse signal generated through the microphone.

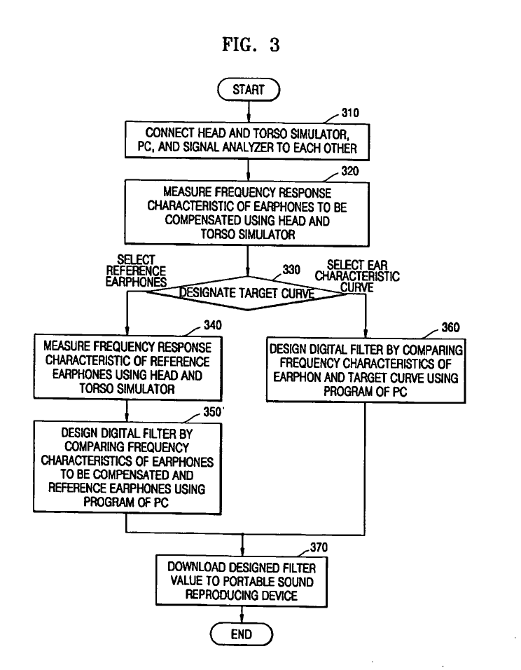

FIG. 3 is a flowchart illustrating a method of compensating for the frequency characteristic of the earphones according to an embodiment of the present general inventive concept.

Referring to FIGS. 1-3, the head and torso simulator 110, the signal analyzer 120, and the PC 130 are connected to each other at operation 310. That is, the head and torso simulator 110 is set up, the output of the microphone located inside the ear of the head and torso simulator 110 is connected to the microphone amplifier (not shown), and the output of the microphone amplifier (not shown) can be connected to the signal analyzer 120 using a microphone cable. The signal analyzer 120 can be connected to the PC 130 and the earphones of the head and torso simulator 110 using a communication bus. Alternatively, a wireless connection can be provided. The signal analyzer 120 outputs a random signal in the audio band (20 Hz to 20 KHz) to the earphones of the head and torso simulator 110 using the program installed in the PC 130.

The frequency response characteristic of the earphones to be compensated is measured using the head and torso simulator 110 at operation 320. That is, the signal analyzer 120 outputs a test signal in the audible band (20 Hz to 20 KHz) to the earphones of the head and torso simulator 110. The sound from the earphones passes through the rubber simulated ear canal inside the head and torso simulator 110, and is input to the microphone installed at the location of the eardrum. The signal analyzer 120 analyzes a frequency component of a signal output from the microphone of the head and torso simulator 110. The PC 130 measures the frequency response characteristic of the earphones based on the frequency component of the signal analyzed by the signal analyzer 120.

The PC 130 designates a user-selected frequency response characteristic or the frequency response characteristic of reference earphones as a target curve at operation 330.

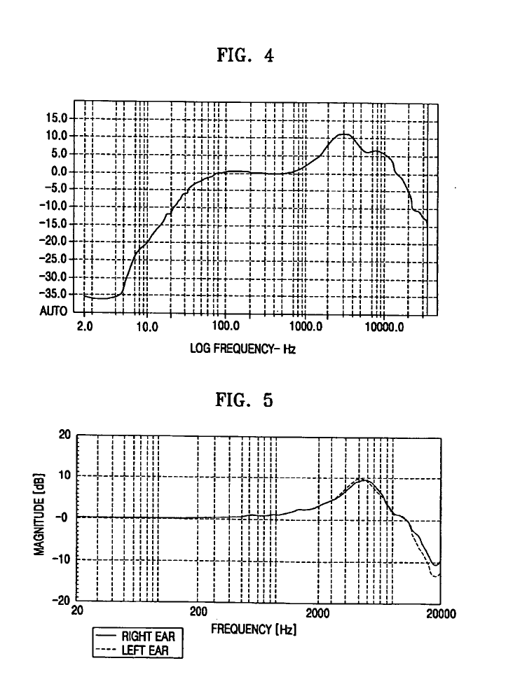

If the reference earphones are selected to designate the target curve, the PC 130 measures and stores the frequency response characteristic of the reference earphones, as illustrated in FIG. 4, using the head and torso simulator 110 at operation 340. Here, the frequency response characteristic of the reference earphones is measured using the same method as for the earphones to be compensated. The program of the PC 130 extracts the difference between the frequency response characteristic of the reference earphones and the frequency response characteristic of the earphones to be compensated, and calculates a filter coefficient to compensate for the extracted difference at operation 350.

If the user-selected frequency response characteristic, e.g., an ear characteristic curve measured in a diffuse field, as illustrated in FIG. 5, is selected as the target curve, the program of the PC 130 extracts the difference between the selected frequency response characteristic and the frequency response characteristic of the earphones to be compensated, and calculates a filter coefficient to compensate for the extracted difference at operation 360.

The PC 130 transmits the filter coefficient calculated at operation 350 or operation 360 to the portable audio device 140 using a communication bus at operation 370.

The portable audio device 140 can produce good sound quality by reflecting the frequency response characteristic of the earphones.

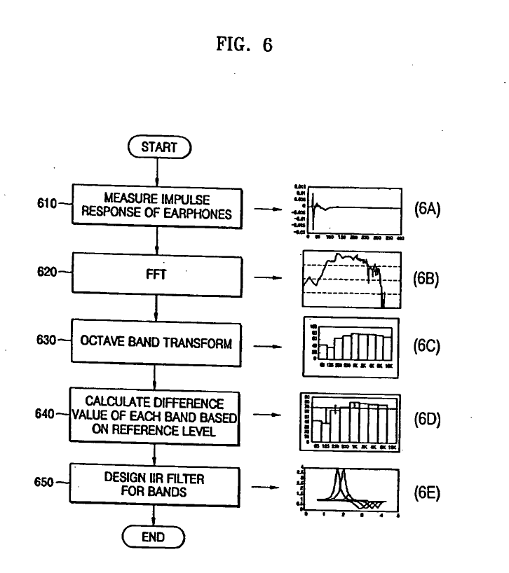

FIG. 6 is a flowchart illustrating a design of a digital filter coefficient to be applied to a portable audio apparatus according to an embodiment of the present general inventive concept.

Referring to FIG. 6, the frequency response characteristic of earphones to be compensated is measured using the head and torso simulator 110 at operation 610. FIG. 6A illustrates an impulse response signal of the earphones, generated by the head and torso simulator 110.

The impulse response signal is transformed from a time domain to a signal of a frequency domain by performing a fast Fourier transform (FFT) on the impulse response signal at operation 620. FIG. 6B illustrates the signal of the frequency domain resulting from the FFT of the impulse response signal illustrated in FIG. 6A.

At operation 630, the FFT impulse response signal is divided into octave bands by performing octave band transformation, and each of the octave bands is represented by a representative sound pressure level. FIG. 6C illustrates the octave bands and the respective representative sound pressure levels.

Differences between a predetermined reference level and the representative sound pressure levels of the octave bands are calculated as illustrated in FIG. 6D at operation 640.

An infinite impulse response (IIR) filter coefficient which reflects the level differences of the octave bands is calculated as illustrated in FIG. 6E at operation 650.

The embodiments of the present general inventive concept can be written as computer programs and can be implemented in general-use digital computers that execute the programs using a computer readable recording medium. Examples of the computer readable recording medium include magnetic storage media (e.g., ROM, floppy disks, hard disks, etc.), optical recording media (e.g., CD-ROMs, DVDs, etc.), and storage media such as carrier waves (e.g., transmission through the internet). The computer readable recording medium can also be distributed over network coupled computer systems such that the computer programs are stored and executed in a distributed fashion.

As described above, according to embodiments of the present general inventive concept, by compensating for a frequency characteristic of earphones by using an ear characteristic curve measured in a diffuse field using a head and torso simulator as a target curve, a frequency response characteristic can be obtained to give the effect of listening to loudspeakers. Also, by compensating for a frequency characteristic of the earphones based on reference earphones, a frequency response characteristic can be similar to a tonal balance of the reference earphones.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An earphone frequency characteristic compensating method comprising:
measuring a frequency response characteristic of earphones considering frequency characteristics of an ear canal;
extracting a filter coefficient by comparing the measured frequency response characteristic of the earphones with a reference frequency characteristic of a target curve; and
compensating for the frequency response characteristic of the earphones based on the extracted filter coefficient.

2. The method of claim 1, wherein the target curve comprises a frequency response characteristic of reference earphones based on a head and torso system.

3. The method of claim 1, wherein the target curve comprises a frequency response characteristic selected by a user.

4. The method of claim 1, wherein the target curve comprises a frequency characteristic curve measured in a diffuse field.

5. The method of claim 1, wherein the extracting of the filter coefficient comprises:
calculating a difference between the frequency response characteristic of the earphones to be compensated and the reference frequency response characteristic of the target curve; and
setting the filter coefficient to compensate for the calculated difference value.

6. The method of claim 1, further comprising:
downloading the extracted filter coefficient to a portable audio device.

7. A filter setting method to compensate for a frequency characteristic of earphones, the method comprising:
measuring a signal response of earphones considering frequency characteristics of an ear canal;
transforming the measured signal response into a signal response of a frequency domain;
dividing the signal response of the frequency domain into bands of a predetermined width and setting a representative sound pressure level for each of the bands;
calculating the differences between the representative sound pressure level of each band and a predetermined reference level; and
setting a filter coefficient based on the calculated differences of the bands.

8. The method of claim 7, wherein the transforming of the measured signal into the signal response of the frequency domain comprises:
performing a fast Fourier transform (FFT) on the measured signal response.

9. The method of claim 7, wherein the dividing of the signal response of the frequency domain into the bands of the predetermined width comprises:
performing octave band transformation on the signal response of the frequency domain.

10. A method of compensating for a frequency response characteristic of earphones, the method comprising:
comparing a frequency response of earphones based on frequency characteristics of a human ear canal with a reference frequency response to calculate a filter coefficient; and
filtering a signal input to the earphones according to the calculated filter coefficient to compensate for the frequency response of the earphones.

11. The method of claim 10, wherein the comparing of the frequency response of the earphones with the reference frequency response comprises:
measuring the frequency response of the earphones; and
comparing the measured frequency response of the ear phones with one of a user-selected reference frequency response and a frequency response of reference ear phones to calculate the filter coefficient.

12. The method of claim 11, wherein the measuring of the frequency response of the earphones comprises:
inputting a random test signal into the earphones; and
receiving an impulse signal in response to the random test signal.

13. The method of claim 11, wherein the comparing of the frequency response of the earphones with the reference frequency response comprises:
transforming the frequency response of the earphones from a time domain to a frequency domain;
dividing the transformed frequency response into octave bands;
calculating differences between representative sound pressure levels of the octave bands and a reference sound pressure level of the reference frequency response; and
calculating an infinite impulse response filter coefficient to reflect to the calculated differences.

14. An earphone frequency characteristic compensating apparatus comprising:
an ear-shaped simulator which includes earphones and microphones;
a signal analyzer to output a stimulus to the ear-shaped simulator and to analyze a frequency of a signal generated by the ear-shaped simulator in response to the stimulus;
an earphone signal compensator to measure a frequency response characteristic of the earphones based on the frequency analyzed by the signal analyzer, to extract a filter coefficient by comparing the measured frequency response characteristic of the earphones with a reference frequency characteristic of a target curve, and to compensate for the frequency response characteristic of the earphones based on the extracted filter coefficient.

15. The apparatus of claim 14, wherein the earphone signal compensator measures the frequency response characteristics of the earphones considering a frequency characteristic of an ear canal, extracts a difference between the measured frequency response characteristics of the earphones and the frequency characteristic of the target curve, and sets the filter coefficient to compensate for the extracted difference.

16. A system to compensate a frequency response characteristic of earphones, comprising:
an ear-shaped simulator to generate a signal in response to an input stimulus and to output the generated signal; and
a signal compensating unit to compare the signal output from the simulator with a target signal and to generate a filter coefficient based on the comparison of the output signal and the target signal.

17. The system of claim 16, wherein the ear-shaped simulator comprises:
earphones to generate the signal in response to the stimulus; and
a microphone to output the generated signal.

18. The system of claim 16, wherein the target signal comprises one of a signal generated by reference earphones and a user-selected signal.

19. The system of claim 18, wherein the user-selected signal comprises an ear characteristic curve measured in a diffuse field.

20. The system of claim 16, wherein the signal compensating unit comprises:
a signal analyzer to analyze a frequency characteristic of the signal output from the microphone; and
a PC to compare the frequency characteristic of the signal with a frequency characteristic of the target signal to generate the filter coefficient.

21. The system of claim 20, wherein the signal analyzer transforms the signal from a time domain to a frequency domain and divides the transformed signal into octave bands, and the PC compares a sound pressure level of each octave band with a reference sound pressure level of the target signal to generate the filter coefficient.

22. The system of claim 16, further comprising:
a portable audio device to download the generated filter coefficient from the signal compensating unit and to output a signal filtered based on the generated filter coefficient to the earphones.

23. A computer readable recording medium having executable code to provide a method to compensate for a frequency characteristic of earphones, the method comprising:
comparing a frequency response of earphones based on frequency characteristics of a human ear canal with a reference frequency response to calculate a filter coefficient; and
filtering a signal input to the earphones according to the calculated filter coefficient to compensate for the frequency response of the earphones.

24. A computer readable recording medium having executable code to provide a method to compensate for a frequency characteristic of earphones, the method comprising:
measuring an impulse response of earphones considering frequency characteristics of an ear canal;
transforming the measured impulse response into an impulse response of a frequency domain;
dividing the impulse response of the frequency domain into bands of a predetermined width and setting a representative sound pressure level for each of the bands;
calculating the differences between the representative sound pressure level of each band and a predetermined reference level; and
setting a filter coefficient based on the calculated differences of the bands.
